(19) United States
(12) Patent Application Publication
(10) Pub. No.: US 2008/0133997 A1
(43) Pub. Date: Jun. 5, 2008

(54) Turbo decoder employing ARP (almost regular permutation) interleave and inverse thereof as de-interleave

(75) Inventors: Tak K. Lee, Irvine, CA (US); Ba-Zhong Shen, Irvine, CA (US)

Correspondence Address: GARLICK HARRISON & MARKISON, P.O. BOX 160727, AUSTIN, TX, 78716-0727, US

(73) Assignee: Broadcom Corporation, a California Corporation, Irvine, CA (US)

(21) Appl. No.: 11/657,819

(22) Filed: Jan. 25, 2007

Related U.S. Application Data
(60) Provisional application No. 60/872,367, filed on Dec. 1, 2006.

(51) Int. Cl. H03M 13/00

(52) U.S. Cl. 714/755

(57) ABSTRACT

Turbo decoder employing ARP (almost regular permutation) interleave and inverse thereof as de-interleave. A novel means is presented herein by which a common module can perform both ARP interleaving and ARP de-interleaving during turbo decoding processing. A novel approach is presented that allows a common structure to perform both the interleaving and de-interleaving operations. In some embodiments, certain ARP interleaving parameters are processed to generate ARP de-interleaving parameters. In even other embodiments, certain ARP interleaving parameters are processed to generate an algebraic, closed form ARP de-interleaver function that can be employed during turbo decoding processing. This novel approach obviates the need for extremely large pre-computed look-up-tables. Moreover, this novel approach can accommodate many different interleaves and information block sizes with very little overhead.

### CROSS REFERENCE TO RELATED PATENTS/PATENT APPLICATIONS

### Provisional Priority Claims

The present U.S. Utility Patent Application claims priority pursuant to 35 U.S.C. §119(e) to the following U.S. Provisional Patent Application which is hereby incorporated herein by reference in its entirety and made part of the present U.S. Utility patent application for all purposes:

1. U.S. Provisional Application Ser. No. 60/872,367, entitled “Turbo decoder employing ARP (almost regular permutation) interleave and inverse thereof as de-interleave,” (Attorney Docket No. BP5864), filed Dec. 1, 2006, pending.

### BACKGROUND OF THE INVENTION

1. Technical Field of the Invention

The invention relates generally to communication systems; and, more particularly, it relates to communication systems employing turbo coding.

2. Description of Related Art

Data communication systems have been under continual development for many years. One such type of communication system that has been of significant interest lately is a communication system that employs iterative error correction codes. Of those, one particular type of communication system that has received interest in recent years has been one which employs turbo codes (one type of iterative error correcting code). Communications systems with iterative codes are often able to achieve lower bit error rates (BER) than alternative codes for a given signal to noise ratio (SNR).

A continual and primary directive in this area of development has been to try continually to lower the SNR required to achieve a given BER within a communication system. The ideal goal has been to try to reach Shannon's limit in a communication channel. Shannon's limit may be viewed as being the data rate to be used in a communication channel, having a particular SNR, that achieves error free transmission through the communication channel. In other words, the Shannon limit is the theoretical bound for channel capacity for a given modulation and code rate.

The use of turbo codes providing such relatively lower error rates, while operating at relatively low data throughput rates, has largely been in the context of communication systems having a large degree of noise within the communication channel and where substantially error free communication is held at the highest premium. Some of the earliest application arenas for turbo coding were space related where accurate (i.e., ideally error free) communication is often deemed an essential design criterion. The direction of development then moved towards developing terrestrial-applicable and consumer-related applications. Still, based on the heritage of space related application, the focus of effort in the turbo coding environment then continued to be achieving relatively lower error floors, and not specifically towards reaching higher throughput.

More recently, focus in the art has been towards developing turbo coding, and variants thereof, that are operable to support higher amounts of throughput while still preserving the relatively low error floors offered within the turbo code context.

Generally speaking, within the context of communication systems that employ turbo codes, there is a first communication device at one end of a communication channel with encoder capability and second communication device at the other end of the communication channel with decoder capability. In many instances, one or both of these two communication devices includes encoder and decoder capability (e.g., within a bi-directional communication system).

### BRIEF SUMMARY OF THE INVENTION

The present invention is directed to apparatus and methods of operation that are further described in the following Brief Description of the Several Views of the Drawings, the Detailed Description of the Invention, and the claims. Other features and advantages of the present invention will become apparent from the following detailed description of the invention made with reference to the accompanying drawings.

### BRIEF DESCRIPTION OF THE SEVERAL VIEWS OF THE DRAWINGS

FIG. 1 illustrates an embodiment of a communication system.

FIG. 2 illustrates an embodiment of a turbo decoder.

FIG. 3 illustrates an embodiment of a turbo decoder employing a single module that is operable to perform both interleaving and de-interleaving.

FIG. 4 illustrates an embodiment of a turbo decoder employing a first module that is operable to perform both interleaving and de-interleaving and a second module that is operable to perform both soft-in/soft-out (SISO) decoding operations.

FIG. 5 illustrates another embodiment of a communication system.

FIG. 6 illustrates another embodiment of a communication system.

FIG. 7 illustrates an embodiment of a method for decoding a turbo coded signal.

### DETAILED DESCRIPTION OF THE INVENTION

Many communication systems incorporate the use of a turbo code. While there are many potential applications that can employ turbo codes, means are presented herein that can be applied to the 3GPP channel code to support an arbitrary number of information bits. Some examples of the number of bits that can be supported using the various aspects of the invention presented herein are 40 to 5114 for WCDMA and HSDPA and more for LTE.

Additional information regarding the UTRA-UTRAN Long Term Evolution (LTE) and 3GPP System Architecture Evolution (SAE) can be found at the following Internet web site:

www.3gpp.org

Within the channel coding system in 3GPP LTE, there is a need and desire to supply and provide for a wide range of block sizes (i.e., turbo code block lengths). Furthermore, turbo decoding of this system generally needs to be implemented using a parallel decoding arrangement because of the very high data throughput and large block size desired. The parallel decoding requires the contention-free memory accessing (i.e., any one turbo decoder (of a group of parallel arranged turbo decoders) accesses only memory (of a group of parallel arranged memories) at any given time). Turbo coding was suggested for 3GPP LTE channel coding. For this coding system, the algebraic interleave referred to as the “almost regular permutation (ARP)” in reference [1] is considered as one of the candidates.

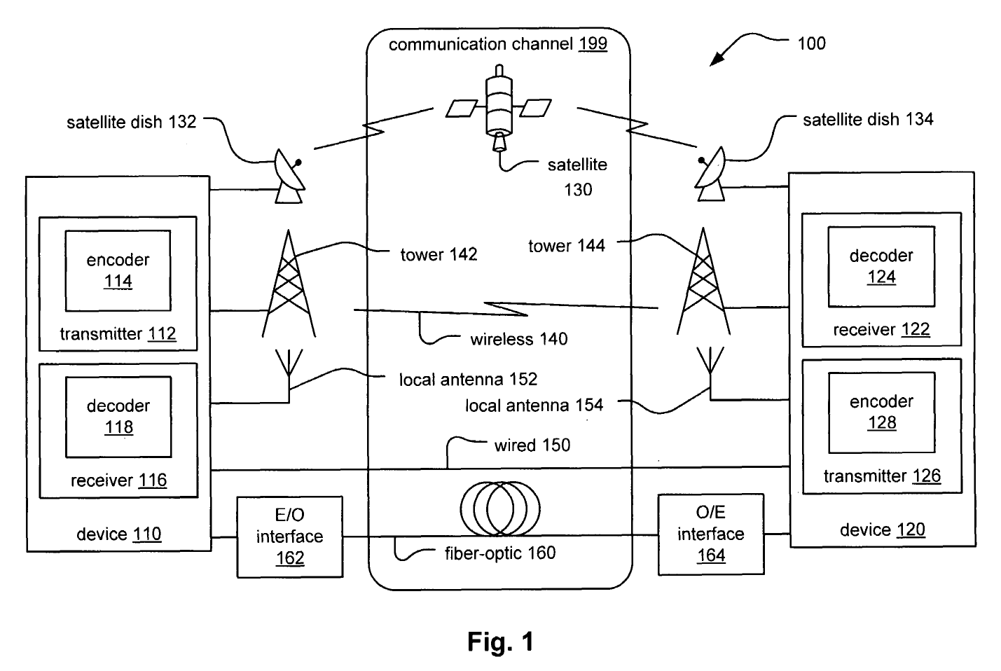

The goal of digital communications systems is to transmit digital data from one location, or subsystem, to another either error free or with an acceptably low error rate. As shown in FIG. 1, data may be transmitted over a variety of communications channels in a wide variety of communication systems: magnetic media, wired, wireless, fiber, copper, and other types of media as well.

FIG. 1 is a diagram illustrating an embodiment of a communication system 100.

Referring to FIG. 1, this embodiment of a communication system 100 is a communication channel 199 that communicatively couples a communication device 110 (including a transmitter 112 having an encoder 114 and including a receiver 116 having a decoder 118) situated at one end of the communication channel 199 to another communication device 120 (including a transmitter 126 having an encoder 128 and including a receiver 122 having a decoder 124) at the other end of the communication channel 199. In some embodiments, either of the communication devices 110 and 120 may only include a transmitter or a receiver. There are several different types of media by which the communication channel 199 may be implemented (e.g., a satellite communication channel 130 using satellite dishes 132 and 134, a wireless communication channel 140 using towers 142 and 144 and/or local antennae 152 and 154, a wired communication channel 150, and/or a fiber-optic communication channel 160 using electrical to optical (E/O) interface 162 and optical to electrical (O/E) interface 164)). In addition, more than one type of media may be implemented and interfaced together thereby forming the communication channel 199.

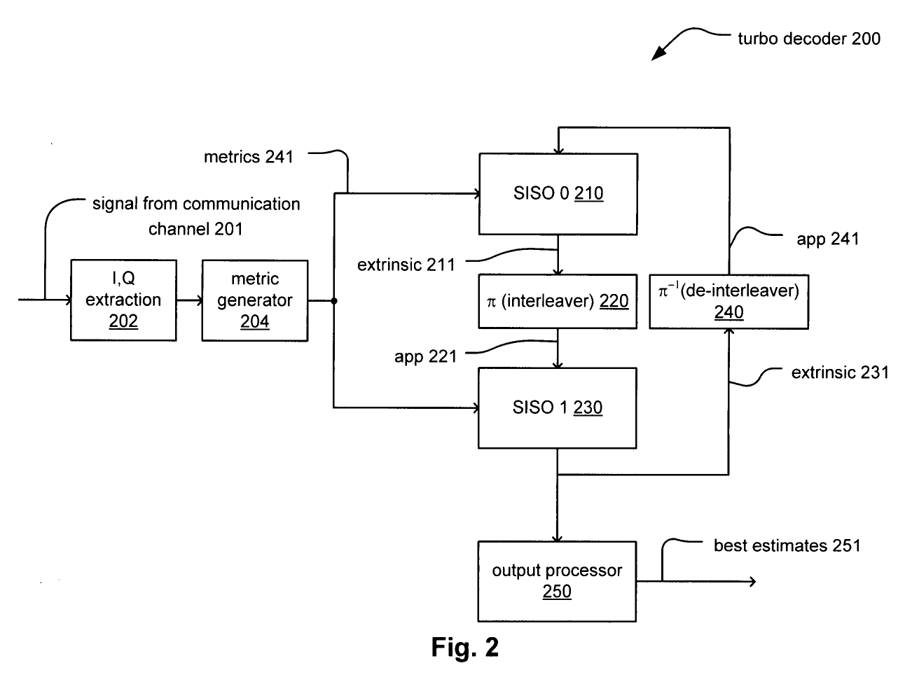

FIG. 2 illustrates an embodiment of a turbo decoder 200. A received signal (e.g., typically received from a communication channel) is provided to an I,Q extraction module 202 that extracts the I,Q (in-phase and quadrature) components from the received signal 201. This may be viewed as being receiver pre-processing, and it can include any appropriate frequency conversion (typically down-conversion from a carrier frequency, if needed). The I,Q can then be mapped according to the modulation's appropriate constellation and mapping. Then, the mapped I,Q is passed to a metric generator 204. The metric generator 204 generates the appropriate metrics 241 that are measured from the received I,Q to the constellation points within the modulation's appropriate constellation and mapping; the metrics are indexed by the mapping of the constellation points within the modulation; these metrics may be viewed as being the scaled Euclidian distances from the location of the actual received symbol to the expected constellation point locations within the modulation.

Continuing on with the turbo decoding process and functionality, the metrics 241 that are calculated by the metric generator 204 are then provided simultaneously to a first soft-in/soft-out (SISO 0) decoder 210 and a second SISO 1 decoder 230. In the context of trellis coding (e.g., turbo trellis coded modulation (TTCM)), each of the first SISO 0 decoder 210 and the second SISO 1 decoder 230 calculates forward metrics (alphas) and backward metrics (betas), and extrinsic values according to the trellis employed.

These alphas, betas, and extrinsics are all calculated for each symbol within a frame that is to be decoded. These calculations of alphas, betas, and extrinsics are all based on the trellis.

Starting with the first SISO 0 decoder 210, after the extrinsic values 211 have been calculated, they are passed to an interleaver (π) 220 after which it is passed to the second SISO 1 decoder 230 as “a priori probability” (app) information 221. Similarly, after extrinsic values 231 have been calculated within the second SISO 1 decoder 230, they are passed to a de-interleaver (π⁻¹) 240 after which it is passed to the first SISO 0 decoder 210 as “a priori probability” (app) information 241. It is noted that a single decoding iteration, within the iterative decoding process of the turbo decoder 200 consists of performing two SISO operations; that is to say, the iterative decoding process must pass through both the first SISO 0 decoder 210 and through the second SISO 1 decoder 230.

After a significant level of confidence has been achieved and a solution is being converged upon, or after a predetermined number of decoding iterations have been performed, then the output from the second SISO 1 decoder 230 is passed as output to an output processor 250. The operation of the SISOs 210 and 230 may generally be referred to as calculating soft symbol decisions of the symbol contained within the received symbol. These soft symbol decisions may be performed on a true bit level in certain embodiments. The output processor 250 uses these soft symbol decisions to generate best estimates 251 (e.g., hard bit and/or symbol decisions) for the information bits that have been encoded within the original turbo coded signal (e.g., generally within a turbo encoder location at another end of a communication channel into which the signal 201 was originally launched.

Many of the embodiments presented herein employ various embodiments of the ARP (almost regular permutation) interleaves. An ARP (almost regular permutation) of information block size L=CW (i.e. C is a divider of L) introduced in reference [1] is defined by

i=π(j)=jP+θ+A(jmodC)P+B(jmodC) mod L

where P is relative prime to L, θ is a constant and A(x) and B(x) are integer function defined on{0,1, . . . ,C−1}. To insure the function defined the function is a permutation (i.e. one to one and on to), in reference [1]A(x) and B(x) are further restricted to

A(i)P+B(i)=C[α(i)P+β(i)],i=0, . . . ,C−1

where α and β are integer functions. In this document, we call C the dithering cycle of the ARP.

As can be seen, C|L (thus gcd(C,P)=1), and therefore π(j)≠π(j′) implies that j≠j′.

### EXAMPLE 1

A first example of an ARP interleave is provided here:

$$y = π ( x ) = Px + C [ α ( x mod C ) P + β ( x mod C ) ] ( mod L )$$

$$L = 24 , C = 4 , P = 7$$

$$α ( u ) = \{ \begin{matrix}0 & if u = 0 \\ 0 & if u = 1 \\ 1 & if u = 2 \\ 1 & if u = 3\end{matrix} , and β ( u ) = \{ \begin{matrix}0 & if u = 0 \\ 1 & if u = 1 \\ 1 & if u = 2 \\ 1 & if u = 3\end{matrix} ,$$

which indicates that

$$π ( x ) = \{ \begin{matrix} xP mod L & if x = 0 mod 4 \\ ( xP + 4 ) mod L & if x = 1 mod 4 \\ ( xP + 4 P + 4 ) mod L & if x = 2 mod 4 \\ ( xP + 4 P + 4 ) mod L & if x = 3 mod 4\end{matrix}$$

If the inputs of the following are provided to such an ARP interleave (π), 0,1,2,3, x 4,5,6,7, x 8,9,10,11, x 12,13,14,15, x 16,17,18,19, x 20,21,22,23, then the output thereof is as follows:

0,11,22,5, x 4,15,2,9, x 8,19,6,13, x 12,23,10,17, x 16,3,14,21, x 20,7,18,1.

### EXAMPLE 2

A second example of an ARP interleave is provided here:

$$y = π ( x ) = Px + C [ α ( x mod C ) P + β ( x mod C ) ] ( mod L )$$

$$L = 20 , C = 4 , P = 3$$

$$A ( u ) = \{ \begin{matrix}0 & if u = 0 \\ 0 & if u = 1 \\ 3 & if u = 2 \\ 1 & if u = 3\end{matrix} , and B ( u ) = \{ \begin{matrix}0 & if u = 0 \\ 2 & if u = 1 \\ 0 & if u = 2 \\ 2 & if u = 3\end{matrix} , and θ = 1. \\ π ( x ) = \{ \begin{matrix} xP + 1 mod L & if x = 0 mod 4 \\ ( xP + 2 + 1 ) mod L & if x = 1 mod 4 \\ ( xP + 3 P + 1 ) mod L & if x = 2 mod 4 \\ ( xP + 1 P + 2 + 1 ) mod L & if x = 3 mod 4\end{matrix}$$

If the inputs of the following are provided to such an ARP interleave (π), 0,1,2,3, x 4,5,6,7, x 8,9,10,11, x 12,13,14,15, x 16,17,18,19 then the output thereof is as follows:

1,6,16,15, x 13,18,8,7, x 5,10,0,19, x 17,2,12,11, x 9,14,4,3.

There are some special cases for ARP as well.

Case 1:

When θ=0, equations (10), (11) and (12) in reference [1].

When θ=3, C=4, [2] France Telecom, GET, “Enhancement of Rel. 6 turbo Code,” 3GPP TSG RAN WG1#43, R1-051310, 2005

When θ=3, C=4 and 8, Table 1, [3] Motorola, “A contention-free interleaver design for LTE codes,”, 3GPP TSG RAN WG1#47.

Case 2:

equations (13) in reference [1].

In addition, certain properties of ARP are also provided below:

Property 1:

x₀=x₁ mod C implies that π(x₀)=π(x₁)mod C.

Proof: Set x₁=x₀+kC. Then π(x₁)−π(x₀)=PkC=0 mod C.

Property 2:

Define Ψ: {0,1, . . . C−1} [symbol] {0,1, . . . C−1} by Ψ(u)=π(u) mod C.

π is a permutation implies that Ψ is a bijection.

Proof: Assume u_{0,}u₁ε {0,1, . . . C−1},u₀≠u₁, but Ψ(u₀)=Ψ(u₁). There are L/C elements in {0,1, . . . L−1} congruent u₀ modulo C and another L/C elements congruent u₁ modulo C. So, by property 1, there are 2L/C elements u such that π(u) have the same congruence module C. This contradicts the hypothesis that π is a permutation.

Property 3:

Define Ψ:{0,1, . . . C−1} [symbol] {0,1, . . . C−1} by Ψ(u)=π(u) mod C.

Ψ is a bijection, then π is a permutation.

Proof: Assume x_{0,}x₁ε {0,1, . . . L−1},x₀<x₁, but π(x₀)=π(x₁). Let u₀=x₀ mod C and u₁=x₁ mod C. If u₀≠u₁, then π(x₀) mod C≠π(x₁) mod C since Ψ is a bijection. If u₀=u₁, then let x₁=x₀+kC for a k ε {0,1, . . . ,L/C−1}. So, π(x₁)−π(x₀)=PkC mod L. Since gcd(P,L)=1 and C|L, PkC mod L=0 implies k=0 or k divides L/C. By the range on k, a contradiction cannot be avoided; so, π(x₀)=π(x₁) can only occur if x₀=x₁.

Referring back to the embodiment of FIG. 2, it is also noted that the interleaving performed within the interleaver (π) 220 can be performed using an embodiment of an ARP interleave. As described herein, a novel approach is presented herein by which an ARP de-interleave can be generated from an ARP interleave. As such, it is noted that the de-interleaving performed within the de-interleaver (π⁻¹) 240 can be performed using an embodiment of an ARP de-interleave that has been generated from an ARP interleave.

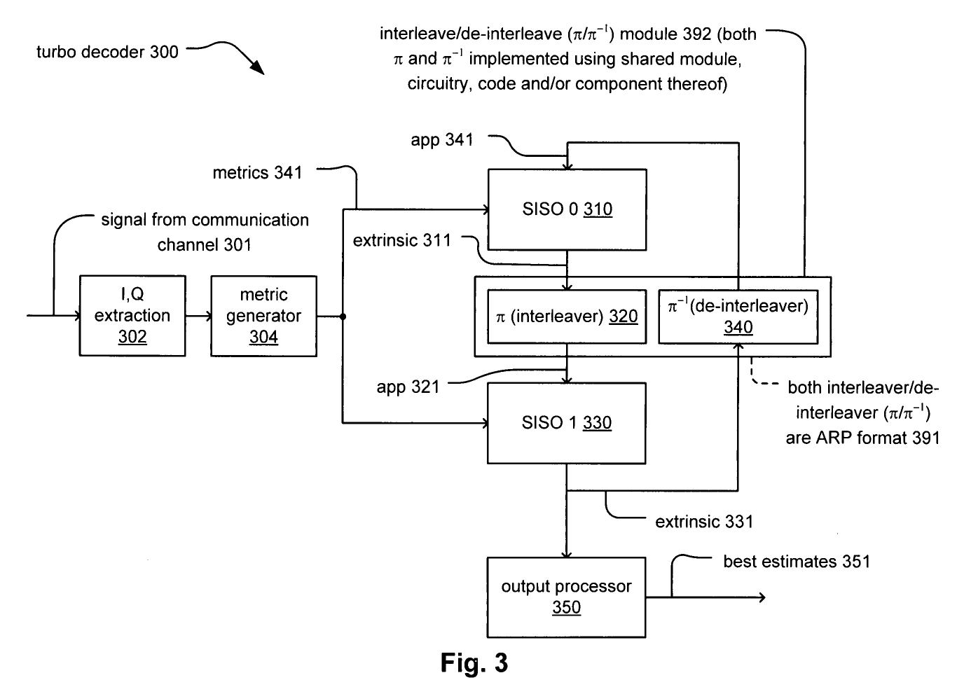

FIG. 3 illustrates an embodiment of a turbo decoder 300 employing a single module that is operable to perform both interleaving and de-interleaving. This embodiment is analogous to the previous embodiment, with one of the differences being that a single interleaver/de-interleaver (π/π⁻¹) module 350 is employed to perform both the interleaving and de-interleaving during the turbo decoding.

A received signal (e.g., typically received from a communication channel) is provided to an I,Q extraction module 302 that extracts the I,Q (in-phase and quadrature) components from the received signal 301. This may be viewed as being receiver pre-processing, and it can include any appropriate frequency conversion (typically down-conversion from a carrier frequency, if needed). The I,Q can then be mapped according to the modulation's appropriate constellation and mapping. Then, the mapped I,Q is passed to a metric generator 304. The metric generator 304 generates the appropriate metrics 341 that are measured from the received I,Q to the constellation points within the modulation's appropriate constellation and mapping; the metrics are indexed by the mapping of the constellation points within the modulation; these metrics may be viewed as being the scaled Euclidian distances from the location of the actual received symbol to the expected constellation point locations within the modulation.

Continuing on with the turbo decoding process and functionality, the metrics 341 that are calculated by the metric generator 304 are then provided simultaneously to a first soft-in/soft-out (SISO 0) decoder 310 and a second SISO 1 decoder 330. In the context of trellis coding (e.g., turbo trellis coded modulation (TTCM)), each of the first SISO 0 decoder 310 and the second SISO 1 decoder 330 calculates forward metrics (alphas) and backward metrics (betas), and extrinsic values according to the trellis employed.

These alphas, betas, and extrinsics are all calculated for each symbol within a frame that is to be decoded. These calculations of alphas, betas, and extrinsics are all based on the trellis.

Starting with the first SISO 0 decoder 310, after the extrinsic values 311 have been calculated, they are passed to an interleaver (π) 320 (implemented within the single interleaver/de-interleaver (π/π⁻¹) module 350) after which it is passed to the second SISO 1 decoder 330 as “a priori probability” (app) information 321. Similarly, after extrinsic values 331 have been calculated within the second SISO 1 decoder 330, they are passed to a de-interleaver (π⁻¹) 340 (also implemented within the same, single interleaver/de-interleaver (π/π⁻¹) module 350) after which it is passed to the first SISO 0 decoder 310 as “a priori probability” (app) information 341. It is noted that a single decoding iteration, within the iterative decoding process of the turbo decoder 300 consists of performing two SISO operations; that is to say, the iterative decoding process must pass through both the first SISO 0 decoder 310 and through the second SISO 1 decoder 330.

After a significant level of confidence has been achieved and a solution is being converged upon, or after a predetermined number of decoding iterations have been performed, then the output from the second SISO 1 decoder 330 is passed as output to an output processor 350. The operation of the SISOs 310 and 330 may generally be referred to as calculating soft symbol decisions of the symbol contained within the received symbol. These soft symbol decisions may be performed on a true bit level in certain embodiments. The output processor 350 uses these soft symbol decisions to generate best estimates 351 (e.g., hard bit and/or symbol decisions) for the information bits that have been encoded within the original turbo coded signal (e.g., generally within a turbo encoder location at another end of a communication channel into which the signal 301 was originally launched.

As with previous embodiments, it is also noted that the interleaving performed within the interleaver (π) 320 (implemented within the single interleaver/de-interleaver (π/π⁻¹) module 392) can be performed using an embodiment of an ARP interleave, as shown by reference numeral 391. As described herein, a novel approach is presented herein by which an ARP de-interleave can be generated from an ARP interleave. As such, it is noted that the de-interleaving performed within the de-interleaver (π¹) 340 (also implemented within the same, single interleaver/de-interleaver (π/π⁻¹) module 392) can be performed using an embodiment of an ARP de-interleave that has been generated from an ARP interleave, as shown by reference numeral 391.

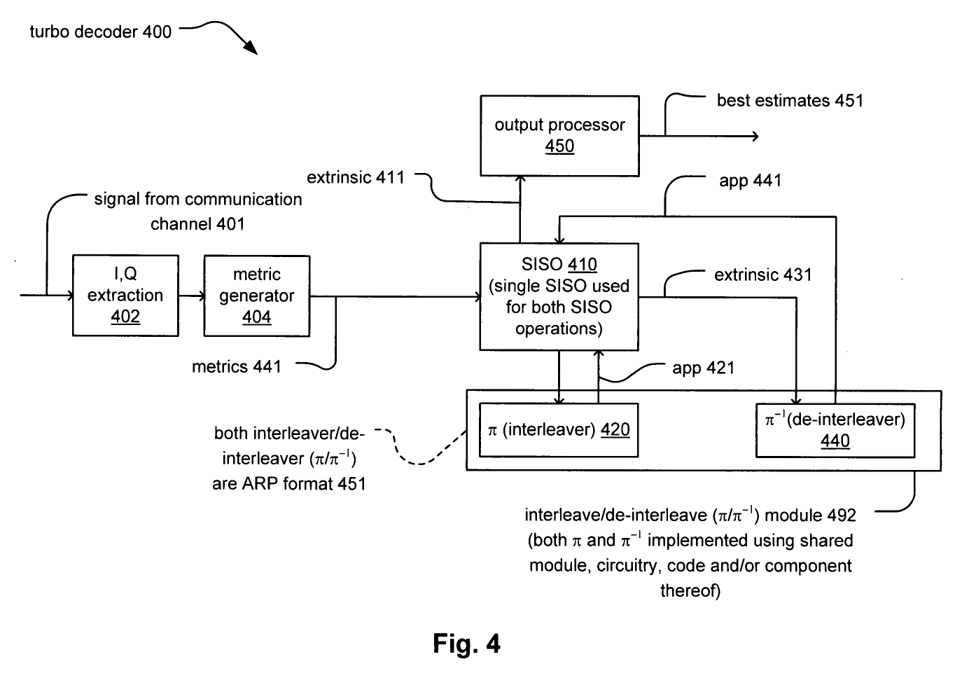

FIG. 4 illustrates an embodiment of a turbo decoder 400 employing a first module that is operable to perform both interleaving and de-interleaving and a second module that is operable to perform both soft-in/soft-out (SISO) decoding operations. This embodiment is somewhat analogous to the previous embodiments, with some of the differences being (1) that a single interleaver/de-interleaver (π/π⁻¹) module 492 is employed to perform both the interleaving and de-interleaving during the turbo decoding, and (2) a single SISO decoder 410 employed to perform both of the the SISO decoding operations.

A received signal (e.g., typically received from a communication channel) is provided to an I,Q extraction module 402 that extracts the I,Q (in-phase and quadrature) components from the received signal 401. This may be viewed as being receiver pre-processing, and it can include any appropriate frequency conversion (typically down-conversion from a carrier frequency, if needed). The I,Q can then be mapped according to the modulation's appropriate constellation and mapping. Then, the mapped I,Q is passed to a metric generator 404. The metric generator 404 generates the appropriate metrics 441 that are measured from the received I,Q to the constellation points within the modulation's appropriate constellation and mapping; the metrics are indexed by the mapping of the constellation points within the modulation; these metrics may be viewed as being the scaled Euclidian distances from the location of the actual received symbol to the expected constellation point locations within the modulation.

Continuing on with the turbo decoding process and functionality, the metrics 441 that are calculated by the metric generator 404 are then provided to a single SISO decoder 410. In the context of trellis coding (e.g., turbo trellis coded modulation (TTCM)), the single SISO decoder 410 calculates forward metrics (alphas) and backward metrics (betas), and extrinsic values according to the trellis employed.

These alphas, betas, and extrinsics are all calculated for each symbol within a frame that is to be decoded. These calculations of alphas, betas, and extrinsics are all based on the trellis.

Starting with a first operation within the single SISO decoder 410, after the extrinsic values 411 have been calculated, they are passed to an interleaver (π) 420 (implemented within the single interleaver/de-interleaver (π/π⁻¹) module 492) after which it is passed back to the single SISO decoder 410 as “a priori probability” (app) information 421. Similarly, after the next extrinsic values 431 have been calculated within the single SISO decoder 410, they are passed to a de-interleaver (π⁻¹) 440 (also implemented within the same, single interleaver/de-interleaver (π/π⁻¹) module 492) after which it is passed back to the single SISO decoder 410 as “a priori probability” (app) information 441. It is noted that a single decoding iteration, within the iterative decoding process of the turbo decoder 400 consists of performing two SISO operations; that is to say, the iterative decoding process must pass through the single SISO decoder 410 two times.

After a significant level of confidence has been achieved and a solution is being converged upon, or after a predetermined number of decoding iterations have been performed, then the output from the single SISO decoder 410 is passed as output to an output processor 450. The operation of the single SISO decoder 410 may generally be referred to as calculating soft symbol decisions of the symbol contained within the received symbol. These soft symbol decisions may be performed on a true bit level in certain embodiments. The output processor 450 uses these soft symbol decisions to generate best estimates 451 (e.g., hard bit and/or symbol decisions) for the information bits that have been encoded within the original turbo coded signal (e.g., generally within a turbo encoder location at another end of a communication channel into which the signal 401 was originally launched.

As with previous embodiments, it is also noted that the interleaving performed within the interleaver (π) 420 (implemented within the single interleaver/de-interleaver (π/π⁻¹) module 492) can be performed using an embodiment of an ARP interleave. As described herein, a novel approach is presented herein by which an ARP de-interleave can be generated from an ARP interleave. As such, it is noted that the de-interleaving performed within the de-interleaver (π⁻¹) 440 (also implemented within the same, single interleaver/de-interleaver (π/π⁻¹) module 492) can be performed using an embodiment of an ARP de-interleave that has been generated from an ARP interleave.

A novel means is presented herein by which a common module can perform both ARP interleaving and ARP de-interleaving during turbo decoding processing. A novel approach is presented that allows a common structure to perform both the interleaving and de-interleaving operations. In some embodiments, certain ARP interleaving parameters are processed to generate ARP de-interleaving parameters. In even other embodiments, certain ARP interleaving parameters are processed to generate an algebraic, closed form ARP de-interleaver function that can be employed during turbo decoding processing. This novel approach obviates the need for extremely large pre-computed look-up-tables. Moreover, this novel approach can accommodate many different interleaves and information block sizes with very little overhead.

Many of the properties of an ARP interleave have been provided above, and the following provides the details by which an ARP de-interleave can be generated from the ARP interleave. This can be achieved in a variety of ways. For example, in one embodiment, a plurality of ARP interleaver parameters is processed thereby generating a plurality of ARP de-interleaver parameters, and these plurality of ARP interleaver parameters as well as the plurality of ARP de-interleaver parameters can be employed by a interleaver/de-interleaver module. In another embodiment, a plurality of ARP interleaver parameters is processed thereby generating an algebraic, closed form ARP de-interleaver function. This algebraic, closed form ARP de-interleaver function can then be provided to and employed by a interleaver/de-interleaver module for use in performing ARP de-interleaving.

For an ARP interleave, π(x), having the form of

π(x)=[Px+A(x mod C)P+B(x mod C)+θ] mod L, then we can define

Ψ from {0,1, . . . ,C−1} to {0,1, . . . ,C−1} by Ψ(m)=π(m) mod C.

By the fact that π is an ARP permutation with period C, Ψ is a bijection.

Since the range of Ψ from is of C, which is small, then Ψ⁻¹ can be constructed efficiently.

Also, gcd(L,P)=1, which indicates that there exists Q such that PQ≡1 mod L.

So, for any y ε {0,1, . . . ,L−1}, let x=π⁻¹(y), then

π⁻¹(y)=x=((y−θ−B(x mod C))Q−A(x mod C)) mod L

since x mod C=Ψ⁻¹(y mod C), the equation above can be rewritten as follows:

π⁻¹(y)=x=Qy+A′(y mod C)Q+B′(y mod C)+θ′) mod L,

where

A′(y mod C)=−B(Ψ⁻¹(y mod C)), and

B′(y mod C)=−A(Ψ⁻¹(y mod C)), and θ′=−Qθ.

### EXAMPLE 3

Consider the interleave (π) function of Example 1. An example is provided for evaluating an ARP de-interleave (π⁻¹).

y=π(x)=[Px+C[α(x mod C)P+β(x mod C)]+θ](mod L)

Let A(x mod C)=Cα(x mod C), and B(x mod C)=Cβ(x mod C).

L=24, C=4, P=7, θ=0, which then results in Q=7 and θ′=0.

$$Ψ ( u ) = \{ \begin{matrix}0 & if u = 0 \\ 3 & if u = 1 \\ 2 & if u = 2 \\ 1 & if u = 3\end{matrix} ,$$

which then results in

$${Ψ}^{- 1} ( u ) = \{ \begin{matrix}0 & if v = 0 \\ 3 & if v = 1 \\ 2 & if v = 2 \\ 1 & if v = 3\end{matrix} . \\ {A}^{′} ( v ) = \{ \begin{matrix}- B ( {Ψ}^{- 1} ( 0 ) ) = 0 & if v = 0 \\ - B ( {Ψ}^{- 1} ( 1 ) ) = - 4 & if v = 1 \\ - B ( {Ψ}^{- 1} ( 2 ) ) = - 4 & if v = 2 \\ - B ( {Ψ}^{- 1} ( 3 ) ) = - 4 & if v = 3\end{matrix} , and \\ {B}^{′} ( v ) = \{ \begin{matrix}- A ( {Ψ}^{- 1} ( 0 ) ) = 0 & if v = 0 \\ - A ( {Ψ}^{- 1} ( 1 ) ) = - 4 & if v = 1 \\ - A ( {Ψ}^{- 1} ( 2 ) ) = - 4 & if v = 2 \\ - A ( {Ψ}^{- 1} ( 3 ) ) = 0 & if v = 3\end{matrix} . \\ {π}^{- 1} ( y ) = \{ \begin{matrix} yQ mod L & if y = 0 mod 4 \\ ( yQ - 4 Q - 4 ) mod L & if y = 1 mod 4 \\ ( yQ - 4 Q - 4 ) mod L & if y = 2 mod 4 \\ ( yQ - 4 Q ) mod L & if y = 3 mod 4\end{matrix} .$$

If the inputs of the following are provided to such an ARP de-interleave (π⁻¹) as in this Example 1,

0,11,22,5, x 4,15,2,9, x 8,19,6,13, x 12,23,10,17, x 16,3,14,21, x 20,7,18,1

then the output thereof is as follows:

10 0,1,2,3, x 4,5,6,7, x 8,9,10,11, x 12,13,14,15, x 16,17,18,19, x 20,21,22,23.

### EXAMPLE 4

Consider the interleave (π) function of Example 2. Another example is provided for evaluating an ARP de-interleave (π⁻¹).

y=r(x)=[Px+A(x mod C)P+B(x mod C)+θ](mod L)

L=20, C=4, P=3, which then results in Q=7 and θ′=−7.

$$Ψ ( u ) = \{ \begin{matrix}1 & if u = 0 \\ 2 & if u = 1 \\ 0 & if u = 2 \\ 3 & if u = 3\end{matrix} ,$$

which then results in

$${Ψ}^{- 1} ( u ) = \{ \begin{matrix}2 & if v = 0 \\ 0 & if v = 1 \\ 1 & if v = 2 \\ 3 & if v = 3\end{matrix} . \\ {A}^{′} ( v ) = \{ \begin{matrix}- B ( {Ψ}^{- 1} ( 0 ) ) = 0 & if v = 0 \\ - B ( {Ψ}^{- 1} ( 1 ) ) = 0 & if v = 1 \\ - B ( {Ψ}^{- 1} ( 2 ) ) = - 2 & if v = 2 \\ - B ( {Ψ}^{- 1} ( 3 ) ) = - 2 & if v = 3\end{matrix} , and \\ {B}^{′} ( v ) = \{ \begin{matrix}- A ( {Ψ}^{- 1} ( 0 ) ) = - 3 & if v = 0 \\ - A ( {Ψ}^{- 1} ( 1 ) ) = 0 & if v = 1 \\ - A ( {Ψ}^{- 1} ( 2 ) ) = 0 & if v = 2 \\ - A ( {Ψ}^{- 1} ( 3 ) ) = - 1 & if v = 3\end{matrix} . \\ {π}^{- 1} ( y ) = \{ \begin{matrix} yQ - 3 - 7 mod L & if y = 0 mod 4 \\ ( yQ - 7 ) mod L & if y = 1 mod 4 \\ ( yQ - 2 Q - 7 ) mod L & if y = 2 mod 4 \\ ( yQ - 2 Q - 1 - 7 ) mod L & if y = 3 mod 4\end{matrix} .$$

If the inputs of the following are provided to such an ARP de-interleave (π⁻¹) as in this Example 2,

1,6,16,15, x 13,18,8,7, x 5,10,0,19, x 17,2,12,11, x 9,14,4,3

then the output thereof is as follows:

0,1,2,3, x 4,5,6,7, x 8,9,10,11, x 12,13,14,15, x 16,17,18,19.

There also can be some simplification when C divides into A and B (i.e., with no remainder).

If the ARP interleave π(x) has the following form:

y=π(x)=[Px+C[α(x mod C)P+β(x mod C)]+θ](mod L)

Then for u ε {0,1, . . . ,C−1}, the following holds

v=Ψ(u)=π(u) mod C=(Pu+θ) mod C

Since gcd(P,C)=1, then it follows that there exists q_{c} such that q_{c}P=1 mod C.

So, Ψ⁻¹(v)=(q_{c}(v−θ)) mod C.

As can be seen, a algebraic, closed form ARP de-interleaver function (π⁻¹(y)) has been generated from the ARP interleave (π(x)) for this special case when C divides into A and B (i.e., with no remainder).

### EXAMPLE 5

In this situation, the following simplification is applied as shown with respect to Example 3 above:

y=π(x)=Px+C[α(x mod C)P+β(x mod C)](mod L)

L=24, C=4, P=7, θ=0, which then indicates that Q=7, q_{C}=3, θ′=0.

$${α}^{′} ( v ) = \{ \begin{matrix}- β ( 0 mod 4 ) = 0 & if v = 0 \\ - β ( 3 mod 4 ) = - 1 & if v = 1 \\ - β ( 6 mod 4 ) = - 1 & if v = 2 \\ - β ( 9 mod 4 ) = - 1 & if v = 3\end{matrix} , and \\ {β}^{′} ( v ) = \{ \begin{matrix}- α ( 0 mod 4 ) = 0 & if v = 0 \\ - α ( 3 mod 4 ) = - 1 & if v = 1 \\ - α ( 6 mod 4 ) = - 1 & if v = 2 \\ - α ( 9 mod 4 ) = 0 & if v = 3\end{matrix} . \\ {π}^{- 1} ( y ) = \{ \begin{matrix} yQ mod L & if y = 0 mod 4 \\ ( yQ - 4 Q - 4 ) mod L & if y = 1 mod 4 \\ ( yQ - 4 Q - 4 ) mod L & if y = 2 mod 4 \\ ( yQ - 4 Q ) mod L & if y = 3 mod 4\end{matrix} .$$

If the inputs of the following are provided to such an ARP de-interleave (π⁻¹) as in this Example 1,

0,11,22,5, x 4,15,2,9, x 8,19,6,13, x 12,23,10,17, x 16,3,14,21, x 20,7,18,1

then the output thereof is as follows:

0,1,2,3, x 4,5,6,7, x 8,9,10,11, x 12,13,14,15, x 16,17,18,19, x 20,21,22,23.

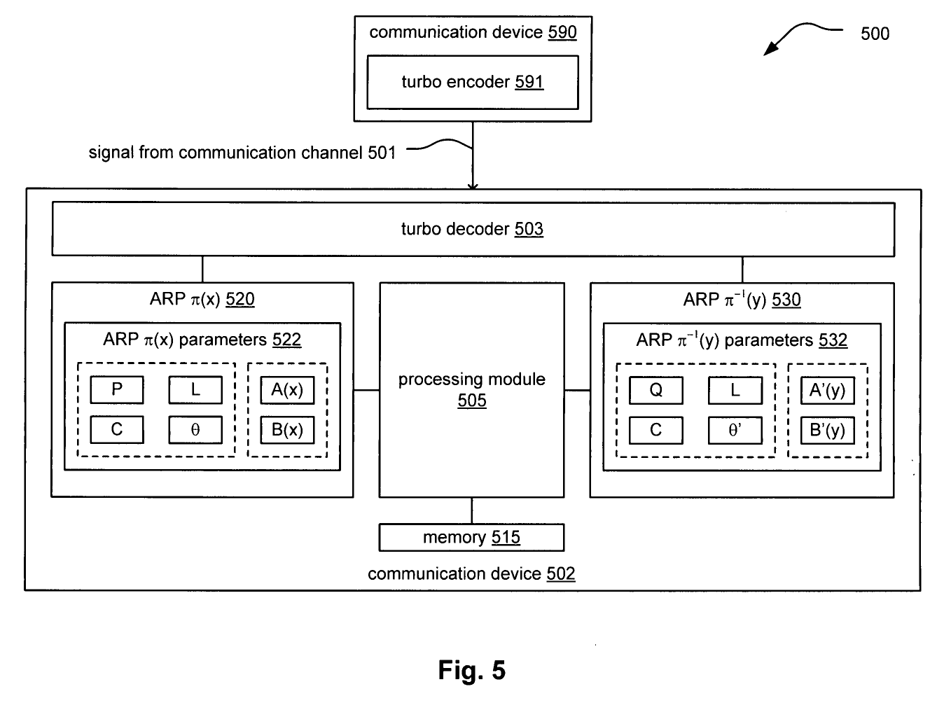

FIG. 5 illustrates another embodiment of a communication system 500. The communication 500 includes a communication device 502 that itself includes a processing module 505 and a memory 515. The memory 515 is coupled to the processing module 505, and the memory 515 is operable to store operational instructions that enable the processing module 505 to perform a variety of functions.

In one embodiment, the processing module 505 is operable to receive a plurality of ARP interleaver π(x) parameters 522 that correspond to an ARP interleave π(x) 520. As shown analogously above with respect to some other embodiments, there are 4 values and 2 functions that are associated with ARP interleave π(x) 520; the 4 values are P, L, C, and θ; and the 2 functions are A(x) and B(x). The processing module 505 is operable to process these plurality of ARP interleaver π(x) parameters 522 and to generate a plurality of ARP de-interleaver π⁻¹(y) parameters 532 that corresponds to an ARP de-interleave π⁻¹(y) 530. As shown analogously above with respect to some other embodiments, there are 4 values and 2 functions that are associated with ARP de-interleave π⁻¹(y) 530; the 4 values are Q, L, C, and θ′; and the 2 functions are A′(y) and B′(y).

Each of the plurality of ARP interleaver π(x) parameters 522 and the plurality of ARP de-interleaver π⁻¹(y) parameters 532 are then provided to an interleaver/de-interleaver module within a turbo decoder 503 that is implemented within the communication device 502 to perform decoding of a turbo coded signal that is received via a communication channel 501. A single architecture (e.g., having ARP format) is operable to perform both the interleaving and de-interleaving in accordance with the turbo decoding processing. The signal 501 is generated by a turbo encoder 591 that is implemented within another communication device 590 situated at another end of the communication channel.

Alternatively, in another embodiment, the processing module 505 is operable to process the plurality of ARP interleaver π(x) parameters 522 that correspond to the ARP interleave π(x) 520 thereby generating an algebraic, closed form ARP de-interleaver function. In such an embodiment, the algebraic, closed form ARP de-interleaver function is provided to an interleaver/de-interleaver module within the turbo decoder 503, and the interleaver/de-interleaver module is then operable to employ the algebraic, closed form ARP de-interleaver function when performing ARP de-interleaving in accordance with the turbo decoding processing.

It is also noted that the processing module 505 can be implemented using a shared processing device, individual processing devices, or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 515 may be a single memory device or a plurality of memory devices. Such a memory device may be a read-only memory, random access memory, volatile memory, non-volatile memory, static memory, dynamic memory, flash memory, and/or any device that stores digital information. Note that when the processing module 505 implements one or more of its functions via a state machine, analog circuitry, digital circuitry, and/or logic circuitry, the memory storing the corresponding operational instructions is embedded with the circuitry comprising the state machine, analog circuitry, digital circuitry, and/or logic circuitry.

This embodiment of FIG. 5 shows a situation where the processing module 505 and the memory 515 coupled thereto are situated outside of and coupled to the turbo encoder 503.

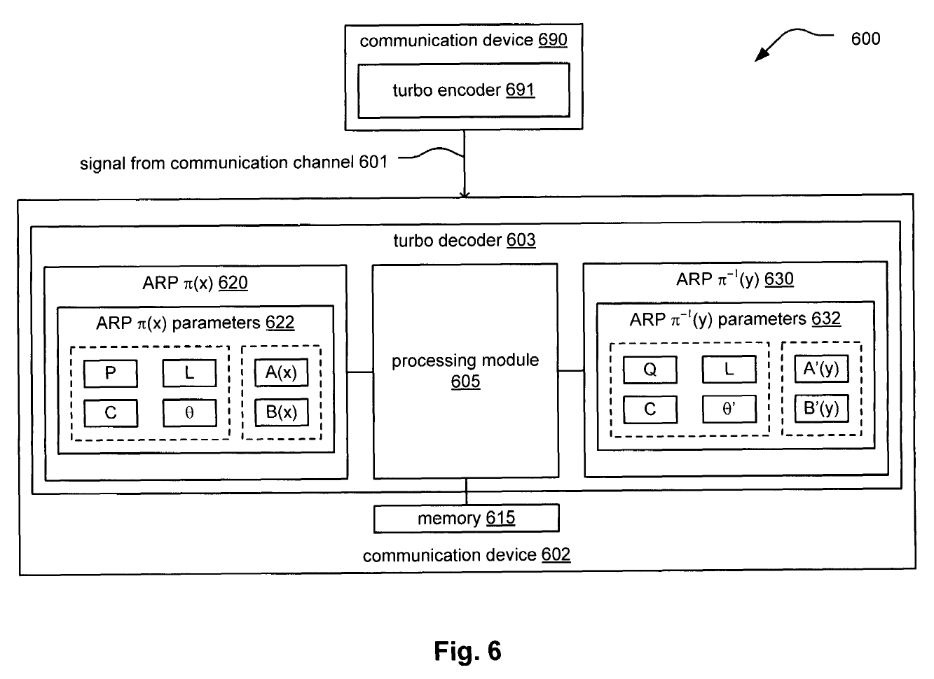

FIG. 6 illustrates another embodiment of a communication system 600. This embodiment of FIG. 6 shows a situation where a processing module 605 is implemented as part of a turbo decoder 603. A memory 615 is shown as being located outside of the turbo decoder 603. However, the memory 615 can be located within the turbo decoder 603 if desired in some embodiments.

The communication 600 includes a communication device 602 that itself includes a processing module 605 and a memory 615. The memory 615 is coupled to the processing module 605, and the memory 615 is operable to store operational instructions that enable the processing module 605 to perform a variety of functions.

In one embodiment, the processing module 605 is operable to receive a plurality of ARP interleaver π(x) parameters 622 that correspond to an ARP interleave π(x) 620. As shown analogously above with respect to some other embodiments, there are 4 values and 2 functions that are associated with ARP interleave π(x) 620; the 4 values are P, L, C, and θ; and the 2 functions are A(x) and B(x). The processing module 605 is operable to process these plurality of ARP interleaver π(x) parameters 622 and to generate a plurality of ARP de-interleaver π⁻¹(y) parameters 632 that corresponds to an ARP de-interleave π⁻¹(y) 630. As shown analogously above with respect to some other embodiments, there are 4 values and 2 functions that are associated with ARP de-interleave π⁻¹(y) 630; the 4 values are Q, L, C, and θ′; and the 2 functions are A′(y) and B′(y).

Each of the plurality of ARP interleaver π(x) parameters 622 and the plurality of ARP de-interleaver π⁻¹(y) parameters 632 are then provided to an interleaver/de-interleaver module within a turbo decoder 603 that is implemented within the communication device 602 to perform decoding of a turbo coded signal that is received via a communication channel 601. A single architecture (e.g., having ARP format) is operable to perform both the interleaving and de-interleaving in accordance with the turbo decoding processing. The signal 601 is generated by a turbo encoder 691 that is implemented within another communication device 690 situated at another end of the communication channel.

Alternatively, in another embodiment, the processing module 605 is operable to process the plurality of ARP interleaver π(x) parameters 622 that correspond to the ARP interleave π(x) 620 thereby generating an algebraic, closed form ARP de-interleaver function. In such an embodiment, the algebraic, closed form ARP de-interleaver function is provided to an interleaver/de-interleaver module within the turbo decoder 603, and the interleaver/de-interleaver module is then operable to employ the algebraic, closed form ARP de-interleaver function when performing ARP de-interleaving in accordance with the turbo decoding processing.

The processing module 605 of this embodiment can be implemented with all of the variations and embodiments as described above with respect to the processing module 505.

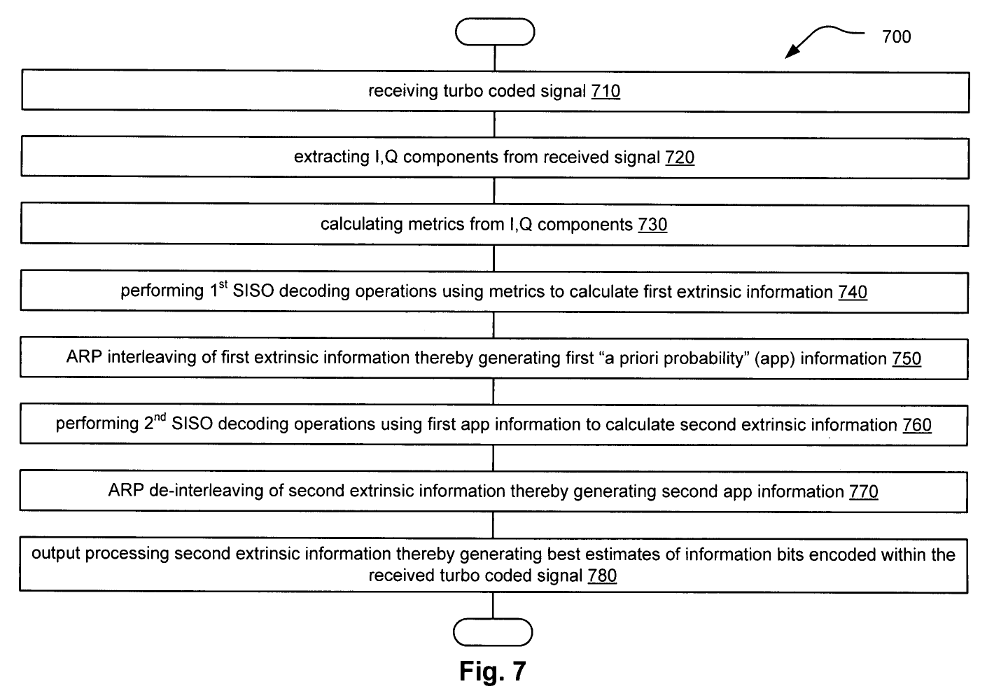

FIG. 7 illustrates an embodiment of a method 700 for decoding a turbo coded signal. The method 700 begins by receiving a turbo coded signal, as shown in a block 710. As shown in a block 720, the method 700 continues by extracting I,Q components from received signal. As shown in a block 730, the method 700 continues by calculating metrics from I,Q components. As shown in a block 740, the method 700 continues by performing 1^{st} SISO decoding operations using metrics to calculate first extrinsic information. As shown in a block 750, the method 700 continues by ARP interleaving of first extrinsic information thereby generating first “a priori probability” (app) information. As shown in a block 760, the method 700 continues by performing 2^{nd} SISO decoding operations using first app information to calculate second extrinsic information. As shown in a block 770, the method 700 continues by ARP de-interleaving of second extrinsic information thereby generating second app information. As shown in a block 780, the method 700 continues by output processing second extrinsic information thereby generating best estimates of information bits encoded within the received turbo coded signal.

Many benefits are provided herein, including (1) a simple algebraic, closed form function can be achieved for evaluating the inverse of an ARP interleave as having the form of another ARP, (2) large look-up-tables can be avoided for finding interleave inverses for very long blocks, and (3) both π and π⁻¹ same have a format that allows for similar design (e.g., a common module, circuitry, code, and/or component thereof can be employed for both).

The present invention has also been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claimed invention.

The present invention has been described above with the aid of functional building blocks illustrating the performance of certain significant functions. The boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality. To the extent used, the flow diagram block boundaries and sequence could have been defined otherwise and still perform the certain significant functionality. Such alternate definitions of both functional building blocks and flow diagram blocks and sequences are thus within the scope and spirit of the claimed invention.

One of average skill in the art will also recognize that the functional building blocks, and other illustrative blocks, modules and components herein, can be implemented as illustrated or by discrete components, application specific integrated circuits, processors executing appropriate software and the like or any combination thereof.

Moreover, although described in detail for purposes of clarity and understanding by way of the aforementioned embodiments, the present invention is not limited to such embodiments. It will be obvious to one of average skill in the art that various changes and modifications may be practiced within the spirit and scope of the invention, as limited only by the scope of the appended claims.

### REFERENCES

[1] C. Berrou, Y. Saouter, C. Douillard, S. Kerouédan, and M. Jézéquel, “Designing good permutations for turbo codes: towards a single model,” 2004 IEEE International Conference on Communications (ICC), Vol.: 1, pp: 341-345, 20-24 Jun. 2004.

[2] France Telecom, GET, “Enhancement of Rel. 6 turbo Code,” 3GPP TSG RAN WG1#43, R1-051310, 2005.

[3] Motorola, “A contention-free interleaver design for LTE codes,” 3GPP TSG RAN WG1#47.

What is claimed is:

1. A turbo decoder, comprising:
a first soft-in/soft-out (SISO) decoder that is operable to:
receive a plurality of metrics associated with a turbo coded signal; and
perform SISO decoding on the plurality of metrics thereby calculating first extrinsic information;
an interleaver/de-interleaver module that is operable to perform almost regular permutation (ARP) interleaving on the first extrinsic information thereby generating first “a priori probability” (app) information; and
a second SISO decoder that is operable to perform SISO decoding on the first app information thereby generating second extrinsic information; and wherein:
the interleaver/de-interleaver module is operable to perform ARP de-interleaving on the second extrinsic information thereby generating second app information.

2. The turbo decoder of claim 1, further comprising:
an output processor that is operable to process most recent extrinsic information that has been generated by the second SISO decoder thereby generating best estimates of information bits encoded within the turbo coded signal.

3. The turbo decoder of claim 1, further comprising:
a processing module; and
a memory, coupled to the processing module, that is operable to store operational instructions that enable the processing module to:
receive a plurality of ARP interleaver parameters;
process the plurality of ARP interleaver parameters thereby generating a plurality of ARP de-interleaver parameters; and
provide the plurality of ARP interleaver parameters and the plurality of ARP de-interleaver parameters to the interleaver/de-interleaver module.

4. The turbo decoder of claim 1, further comprising:
a processing module; and
a memory, coupled to the processing module, that is operable to store operational instructions that enable the processing module to:
process a plurality of ARP interleaver parameters thereby generating an algebraic, closed form ARP de-interleaver function;
provide the algebraic, closed form ARP de-interleaver function to the interleaver/de-interleaver module; and
the interleaver/de-interleaver module is operable to employ the algebraic, closed form ARP de-interleaver function when performing ARP de-interleaving.

5. The turbo decoder of claim 1, wherein:
the interleaver/de-interleaver module is operable to employ a plurality of ARP interleaver parameters when performing ARP interleaving; and
the interleaver/de-interleaver module is operable to employ a plurality of ARP de-interleaver parameters when performing ARP de-interleaving.

6. The turbo decoder of claim 1, wherein:
the interleaver/de-interleaver module is operable to employ a plurality of ARP interleaver parameters when performing ARP interleaving;
the interleaver/de-interleaver module is operable to employ a plurality of ARP de-interleaver parameters when performing ARP de-interleaving; and
the plurality of ARP de-interleaver parameters is generated from the plurality of ARP interleaver parameters.

7. The turbo decoder of claim 1, further comprising:
a memory that is operable to store a first plurality of information corresponding to a plurality of ARP interleaves; and wherein:
the memory is operable to store a second plurality of information corresponding to a plurality of ARP de-interleaves;
the interleaver/de-interleaver module is operable to retrieve first information from the first plurality of information to govern the interleaving performed by the interleaver/de-interleaver module; and
the interleaver/de-interleaver module is operable to retrieve second information from the second plurality of information to govern the de-interleaving performed by the interleaver/de-interleaver module.

8. The turbo decoder of claim 1, wherein:
the interleaver/de-interleaver module is operable to perform a plurality of interleaves and a plurality of de-interleaves.

9. The turbo decoder of claim 1, wherein:
the turbo decoder is implemented within a wireless personal communication device.

10. The turbo decoder of claim 1, wherein:
the turbo decoder is implemented within a communication device; and
the communication device is implemented within at least one of a satellite communication system, a wireless communication system, a wired communication system, and a fiber-optic communication system.

11. A turbo decoder, comprising:
a processing module;
a memory, coupled to the processing module;
a first soft-in/soft-out (SISO) decoder that is operable to:
receive a plurality of metrics associated with a turbo coded signal; and
perform SISO decoding on the plurality of metrics thereby calculating first extrinsic information;
an interleaver/de-interleaver module that is operable to perform almost regular permutation (ARP) interleaving on the first extrinsic information thereby generating first “a priori probability” (app) information; and
a second SISO decoder that is operable to perform SISO decoding on the first app information thereby generating second extrinsic information;
an output processor that is operable to process most recent extrinsic information that has been generated by the second SISO decoder thereby generating best estimates of information bits encoded within the turbo coded signal; and wherein:
the interleaver/de-interleaver module is operable to perform ARP de-interleaving on the second extrinsic information thereby generating second app information;
the interleaver/de-interleaver module is operable to employ a plurality of ARP interleaver parameters when performing ARP interleaving;
the memory, coupled to the processing module, is operable to store operational instructions that enable the processing module to:
process the plurality of ARP interleaver parameters thereby generating a plurality of ARP de-interleaver parameters; and
provide the plurality of ARP de-interleaver parameters to the interleaver/de-interleaver module; and
the interleaver/de-interleaver module is operable to employ the plurality of ARP de-interleaver parameters when performing ARP de-interleaving.

12. The turbo decoder of claim 11, wherein:
the memory, coupled to the processing module, is operable to store operational instructions that enable the processing module to:
process the plurality of ARP interleaver parameters thereby generating an algebraic, closed form ARP de-interleaver function;
provide the algebraic, closed form ARP de-interleaver function to the interleaver/de-interleaver module; and
the interleaver/de-interleaver module is operable to employ the algebraic, closed form ARP de-interleaver function when performing ARP de-interleaving.

13. The turbo decoder of claim 11, wherein:
the interleaver/de-interleaver module is operable to perform a plurality of interleaves and a plurality of de-interleaves.

14. The turbo decoder of claim 11, wherein:
the turbo decoder is implemented within a wireless personal communication device.

15. The turbo decoder of claim 11, wherein:
the turbo decoder is implemented within a communication device; and
the communication device is implemented within at least one of a satellite communication system, a wireless communication system, a wired communication system, and a fiber-optic communication system.

16. A method for decoding a turbo coded signal, comprising:
receiving a plurality of metrics associated with a turbo coded signal;
performing first soft-in/soft-out (SISO) decoding on the plurality of metrics thereby calculating first extrinsic information;
performing almost regular permutation (ARP) interleaving on the first extrinsic information thereby generating first “a priori probability” (app) information using an interleaver/de-interleaver module;
performing second SISO decoding on the first app information thereby generating second extrinsic information;
performing ARP de-interleaving on the second extrinsic information thereby generating second app information using the interleaver/de-interleaver module.

17. The method of claim 16, further comprising:
processing most recent extrinsic information that has been generated during the second SISO decoding thereby generating best estimates of information bits encoded within the turbo coded signal.

18. The method of claim 16, further comprising:
processing a plurality of ARP interleaver parameters thereby generating a plurality of ARP de-interleaver parameters; and
employing the plurality of ARP de-interleaver parameters to perform the ARP de-interleaving.

19. The method of claim 16, further comprising:
processing a plurality of ARP interleaver parameters thereby generating an algebraic, closed form ARP de-interleaver function; and
employing the algebraic, closed form ARP de-interleaver function to perform the ARP de-interleaving.

20. The method of claim 16, wherein:
the method is performed within a communication device; and
the communication device is implemented within at least one of a satellite communication system, a wireless communication system, a wired communication system, and a fiber-optic communication system.
